(19) United States
(12) Patent Application Publication
(10) Pub. No.: US 2009/0049348 A1
(43) Pub. Date: Feb. 19, 2009

(54) SEMICONDUCTOR STORAGE DEVICE

(75) Inventor: Hitoshi IWAI, Kamakura-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/190,936

(22) Filed: Aug. 13, 2008

(30) Foreign Application Priority Data
Aug. 13, 2007 (JP) 2007-210763

(51) Int. Cl. G11C 29/08; G06F 11/263

(52) U.S. Cl. 714/718; 714/E11.177

(57) ABSTRACT

This semiconductor storage device comprises a test mode based on test data input from the outside. A test data register temporarily retains the test data, while a test code register temporarily retains a test code corresponding to the test data. A test-code-match detection circuit detects a match between a test code retained in the test code register and a desired test code to output a match signal. When the match signal is output, a control circuit outputs the test data retained in the test data register to the first one of a plurality of shift registers in a test data latch circuit. Further, the control circuit inputs the test data returned from the last one of the plurality of shift registers in the test data latch circuit.

### CROSS REFERENCE TO RELATED APPLICATIONS

This application is based on and claims the benefit of priority from prior Japanese Patent Application No. 2007-210763, filed on Aug. 13, 2007, the entire contents of which are incorporated herein by reference.

### BACKGROUND OF THE INVENTION

1. Field of the Invention

The present invention relates to a semiconductor storage device, and in particular, to a semiconductor storage device comprising a circuit for transferring test data for use in factory tests or otherwise.

2. Description of the Related Art

Recently, consolidated memory has been widely used in the field of portable electronic devices where reduction in device-size or cost is highly required. Consolidated memory includes memory macros such as SRAM (Static Random Access Memory) or DRAM (Dynamic Random Access Memory) consolidated with logic circuits in one semiconductor substrate. Such consolidated memory provides the SoC (System on Chip).

The memory macros such as DRAM or SRAM are provided with redundant circuits to compensate bad cells for improving yield rate. The redundant circuits compensate any bad cells by replacing them with spare memory cells when some failure has been found in a normal memory cell.

When replacing bad cells with spare memory cells, it is necessary to store bad addresses that specify the bad cells. The bad addresses are stored in a fuse circuit. The bad addresses are specified by analyzing an output signal based on input of test data that is input from an external tester. The data of the bad addresses is stored in the fuse circuit.

In addition, the memory macros require adjustment (trimming) of internal voltage and internal timing signals. The resulting trimming data is also stored in the fuse circuit.

Conventionally, laser fuse circuits are known as one of the most common fuse circuits. The laser fuse circuits fuse wiring in a specific layer with heat generated by irradiation of laser light and stores data depending on whether or not the wiring is cut off.

Since laser fuses are larger in size than semiconductor elements such as transistors and wiring is fused through irradiation of laser light therein, arranging laser fuses in memory macros imposes a significant restriction on floor plans and wiring layouts. Accordingly, some techniques have been proposed where laser fuses are together arranged outside memory macros as a “fuse box” (see, for example, Japanese Patent Laid-Open No. 2004-133970). This scheme is beneficial in that it can reduce restrictions on floor plans and wiring layouts in each memory macro and improve efficiency in cutting fuses.

As mentioned earlier, in testing memory macros, in addition to test data for detecting any bad cells, various types of test data are input, such as test data for adjusting (trimming) internal power supply voltage or internal timing signals during factory tests or other evaluation/analysis operations. After generated by a tester provided outside the memory macros, these types of test data is input to a test control circuit for each memory macro to be tested and evaluated, and then transferred to and stored in latch circuits distributed in each memory macro for testing. The test results are stored in the fuse circuit.

If there is a small amount of test data, then each latch circuit may be connected to the external tester in a parallel manner to input the test data. Alternatively, if there is a large amount of test data, then it is necessary to serially connect multiple latch circuits in each memory macro and transfer test data in a serial manner from the external tester via a test control circuit in each memory macro to multiple latch circuits.

In the latter case, a data transfer control circuit is also required in the test control circuit in each memory macro for controlling transfer to the multiple latch circuits. The data transfer control circuit needs to have latch circuits as many as the multiple latch circuits for storing bit data. Therefore, the more the types of tests, the larger the data transfer control circuit, which would result in increase in circuit area of memory macros.

### SUMMARY OF THE INVENTION

One aspect of the present invention provides a semiconductor storage device with a test mode based on test data input from the outside, comprising: a test data register temporarily retaining the test data; a test code register temporarily retaining a test code corresponding to the test data; a test-code-match detection circuit detecting a match between the test code retained in the test code register and a desired test code to output a match signal; and a control circuit configured to, when the match signal is output, output the test data retained in the test data register to the first one of a plurality of shift registers in a test data latch circuit, the plurality of shift registers being serially connected to transfer the test data in a serial manner, and to start an operation of inputting the test data returned from the last one of the plurality of shift registers in the test data latch circuit.

### BRIEF DESCRIPTION OF THE DRAWINGS

FIG. 1 is a block diagram illustrating an entire configuration of a semiconductor storage device according to a first embodiment of the present invention;

FIG. 2 is a block diagram illustrating in detail a configuration of the data transfer control circuit 15 of FIG. 1;

FIG. 3 is a timing chart illustrating operation of the first embodiment;

FIG. 4 is a block diagram illustrating an entire configuration of a semiconductor storage device according to a second embodiment of the present invention;

FIG. 5 is a block diagram illustrating an entire configuration of a semiconductor storage device according to a third embodiment of the present invention; and

FIG. 6 illustrates a variation of the embodiments.

### DETAILED DESCRIPTION OF THE EMBODIMENTS

Embodiments of the present invention will now be described in detail below with reference to the accompanying drawings.

### First Embodiment

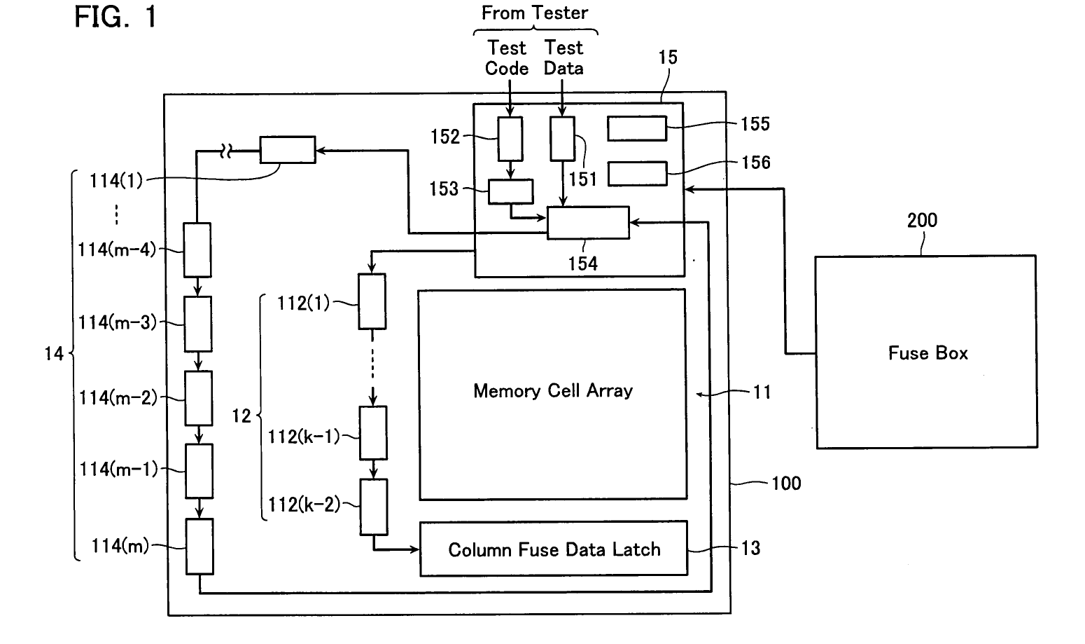

Referring now to a block diagram of FIG. 1, an entire configuration of a semiconductor storage device according to a first embodiment of the present invention will be described below. This semiconductor storage device comprises a memory macro 100 and a fuse box 200.

Although illustration is omitted, the fuse box 200 comprises a plurality of non-volatile storage elements for programming fuse data and a transfer control circuit for governing read and transfer operations of the fuse data. In this case, the non-volatile storage elements may be optical fuses that are fused with laser light to program data or electrical fuses that fuse wiring, etc., through application of high voltage to program data. Additionally, the fuse data includes, for example, trimming data for adjusting the magnitude of internal voltage, frequency of clock signals, or the like, in addition to row redundancy data and column redundancy data stated below.

The memory macro 100 includes a memory cell array 11, a row-fuse-data latch circuit 12, a column-fuse-data latch circuit 13, a test data latch circuit 14, and a data transfer control circuit 15.

The row-fuse-data latch circuit 12 is a circuit to which row redundancy data is transferred and stored in, for replacement in the row direction for each unit in the memory cell array 11. The row-fuse-data latch circuit 12 is configured with a plurality of shift registers 112 (1)-(k) serially connected to each other. The row redundancy data is transferred from the fuse box 200 via a transfer circuit (not illustrated) in the data transfer control circuit 15.

The column-fuse-data latch circuit 13 is a circuit to which column redundancy data is transferred and stored in, for replacement in the column direction for each unit in the memory cell array 11. Although illustration is omitted, the column-fuse-data latch circuit 13 is also configured with a plurality of shift registers serially connected to each other. The column redundancy data is transferred from the fuse box 200 via a transfer circuit (not illustrated) in the data transfer control circuit 15 and the row-fuse-data latch circuit 12.

Note that the row redundancy data and the column redundancy data stored in the row-fuse-data latch circuit 12 and the column-fuse-data latch circuit 13 are used in redundancy control (for replacing bad cells with replacement cells) in a redundancy control circuit (not illustrated).

The test data latch circuit 14 is a circuit in which test data is stored that is provided by an external tester (not illustrated) for execution of different tests. The test data latch circuit 14 is configured with a plurality of shift registers 114 (1)-(m) serially connected to each other. The shift registers 114 (1)-(m) perform data transfer operations according to clock signals CLK. The test data that is transferred to and stored in the test data latch circuit 14 is used for test operations performed by a test control circuit (not illustrated).

If there are a large number of test modes, such many types of test modes may be performed with a small number of input terminals by serially connecting the shift registers in the test data latch circuit 14 and serially transferring the test data in the above-mentioned manner. However, having the test data latch circuit with a serial connection configuration requires the same number of (“m”, in FIG. 1) shift registers to be provided also in the data transfer control circuit, which conventionally leads to increase in size of the data transfer control circuit. To this extent, this embodiment eliminates these problems by providing the following configuration of the data transfer control circuit 15.

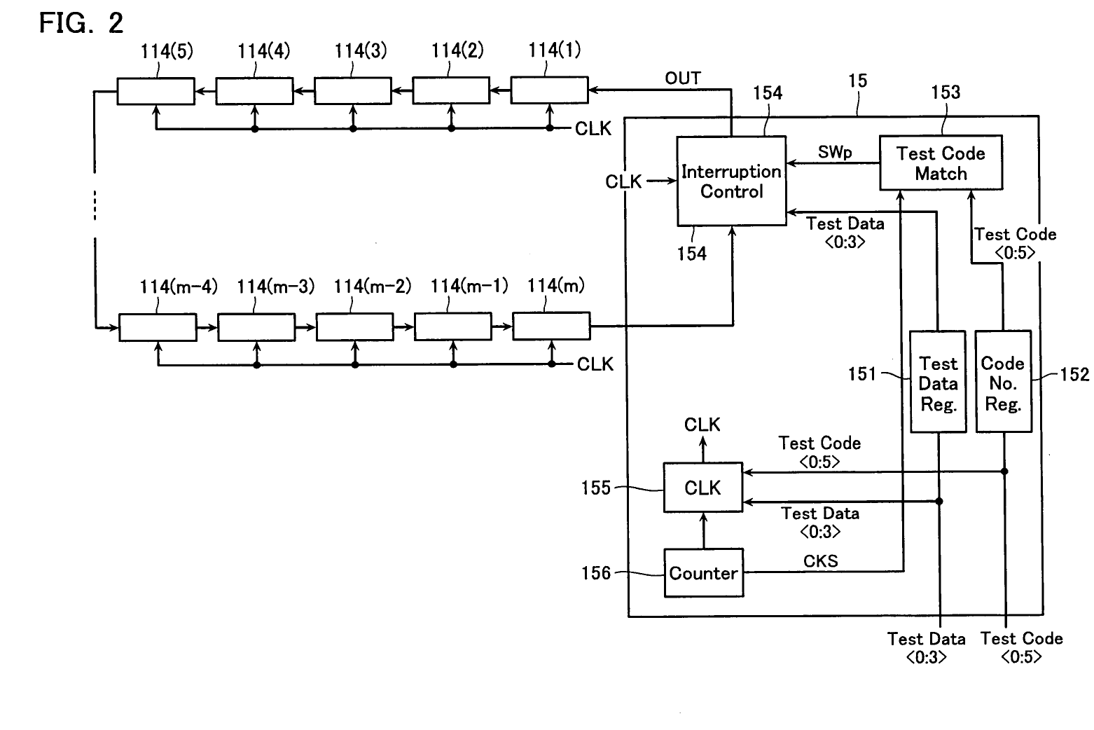

Referring now to FIG. 2, description is made to a configuration of the data transfer control circuit 15 of this embodiment. The data transfer control circuit 15 comprises a test data register 151, a test code register 152, a test-code-match detection circuit 153, an interruption control circuit 154, a clock generation circuit 155, and a clock counter 156. Note that in a factory test or chip evaluation/analysis, the number of test codes to be set at a time would normally be one or two, three at most. In this embodiment, assuming that setting one test code is sufficient, only one test data register 151 and one test code register 152 are provided.

The test data register 151 has a function of temporarily retaining test data TestData<0:3> that is transmitted from an external tester (not illustrated). In this case, as the test data TestData<0:3> is 4-bit data, the test data register 151 has shift registers (not illustrated) sufficient for retaining such 4-bit data.

In addition, the test code register 152 has a function of temporarily retaining a test code TestCode<0:5> corresponding to the test data TestData<0:3> that is transmitted from an external tester (not illustrated) and stored in the test data register 151. In this case, as the test code TestCode<0:5> is 6-bit data, the test code register 152 has shift registers (not illustrated) sufficient for retaining such 6-bit data. That is, the test code TestCode<0:5> of 6 bits can identify sixty-four (64) types of tests.

In addition, the test-code-match detection circuit 153 has a function of detecting whether the test code TestCode<0:5> retained in the test code register 152 matches that of a desired test. If a match is detected, then the test-code-match detection circuit 153 gives a rise in a match signal SWp from “L” to “H”.

In addition, when the above-mentioned match signal SWp becomes “H”, the interruption control circuit 154 outputs the test data TestData<0:3> as an output signal OUT.

The output signal OUT is output to the first shift register 114 (1) included in the test data latch circuit 14 mentioned above. In addition, the output of the last shift register 114 (m) included in the test data latch circuit 14 returns to the interruption control circuit 154. That is, the test data latch circuit 14 in combination with the interruption control circuit 154 forms a closed-loop data transfer path.

The clock generation circuit 155 generates a clock signal CLK for prescribing operations of the interruption control circuit 154 and the shift registers 114 (1)-(m). The clock counter 156 outputs a code count signal CKS that is generated by frequency demultiplication of a clock signal CLK. The code count signal CKS is used to determine whether a desired test code is input to the test-code-match detection circuit 153 mentioned above.

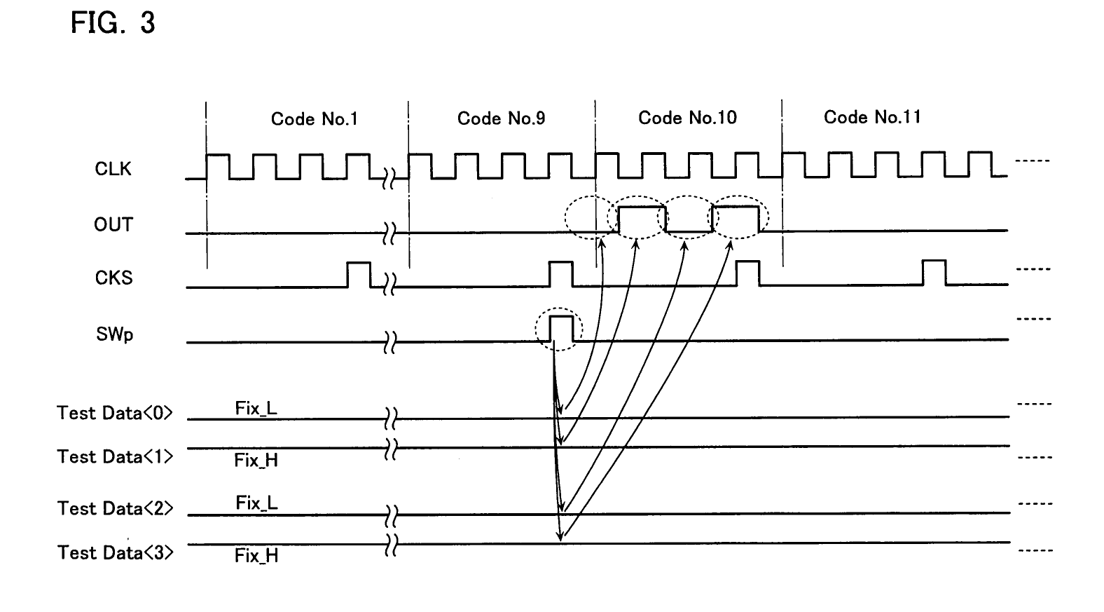

Referring now to a timing chart of FIG. 3, operation of the semiconductor storage device of this embodiment will be described below.

Various types of test codes and the corresponding test data are latched from a tester (not illustrated) to the test code register 152 and the test data register 151 in numeric order. In addition, test codes for a desired test to be performed are separately input to the test-code-match detection circuit 153. A match is detected between the test codes and data retained in the test code register 152 based on a code count signal CKS. In this case, assuming that a test code #10 (Code No. 10) has been input as a code for the test to be performed. In addition, let <0101> be the test data (4 bits) of the test in question. Thus, when the count of pulses for the code count signal CKS reaches ten (10), the test-code-match detection circuit 153 determines that the test code latched in the test code register 152 matches the desired test code.

Upon a match is determined, the test-code-match detection circuit 153 gives a rise in and outputs a match signal SWp from “L” to “H”. Based on the rise of the match signal SWp from “L” to “H”, the interruption control circuit 154 captures the test data TestData<0:3> latched in the test data register 151.

The interruption control circuit 154 transfers the captured test data TestData<0:3> as an output signal OUT to the first shift register 114 (1). Then, the number of pulses for the clock signal CLK, which corresponds to the number of the test code of the captured test data, is input to transfer the test data TestData<0:3> up to a certain shift register 114. As described above, since the shift registers 114 in combination with the interruption control circuit 154 form a closed-loop path, they may program sixty-four (64) types of test codes, one at a time, for example, by inputting desired test codes one after another and cycling them through the closed loop.

As can be seen from the above, in this embodiment, the test-code-match detection circuit 153 is provided and the interruption control circuit 154 programs the test data latched in the test data register 151 within the test data latch circuit 14 according to match detection. Therefore, it is sufficient to latch in the test data register 151 only test data corresponding to the test codes to be executed at a time. Accordingly, this embodiment may mitigate increase in circuit size since there is no need to provide latch circuits in a data transfer circuit as many as the shift registers for latching test data that are serially connected in each memory macro.

Moreover, since a closed loop is formed by the interruption control circuit 154 and the shift registers 114, test data corresponding to one test code captured as mentioned above may be captured thereto in turn.

### Second Embodiment

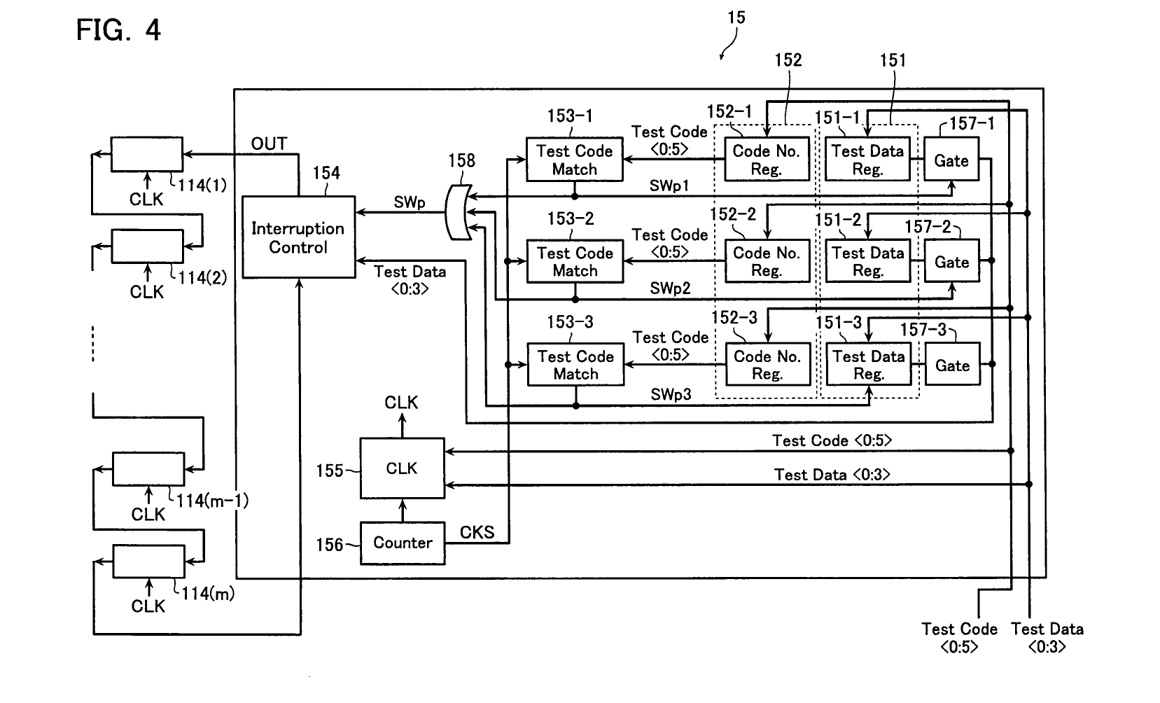

A second embodiment of the present invention will now be described below with reference to the accompanying drawings. The entire configuration of the semiconductor storage device is as illustrated in FIG. 1 and thus has the same configuration as the first embodiment. This embodiment, however, is different from the first embodiment in the configuration of the data transfer control circuit 15. FIG. 4 is a block diagram illustrating the configuration of the data transfer circuit 15 according to the second embodiment. The same reference numerals represent the same components as the first embodiment (FIG. 2) and detailed description thereof will be omitted.

As illustrated in FIG. 4, the data transfer control circuit 15 of this embodiment is different from that of the first embodiment in that it comprises a plurality of (three, in FIG. 4) test data registers 151, test code registers 152, and test-code-match detection circuits 153, respectively. Correspondingly, there are also provided gate circuits 157-1 to 157-3.

The configuration of the device in the first embodiment is based on the assumption that it is sufficient to set one test code at a time. However, for example, factory tests have strict requirements for reducing time for each test. For this purpose, such a configuration is employed in this embodiment that allows three test codes to be set at a time. That is, different desired test codes are input to the test-code-match detection circuits 153-1 to 153-3, each of which separately determines whether or not a respective test code matches another test code stored in a respective test code register 152-1 to 152-3. If a match is determined for any one of the test-code-match detection circuits 153-1 to 153-3, then a match signal SWp1, SWp2 or SWp3 rises to “H”, which is output to an OR gate 158 and one of gate circuits 157-1 through 157-3.

Upon receipt of the match signal SWp1, SWp2 or SWp3, one of the gate circuits 157-1 through 157-3 outputs the test data latched in test data registers 151-1 to 151-3 to the interruption control circuit 154. When any one of the match signals SWp1 to SWp3 becomes “H”, the OR gate gives a rise in the match signal SWp to “H”. Other operations are similar to those of the first embodiment.

### Third Embodiment

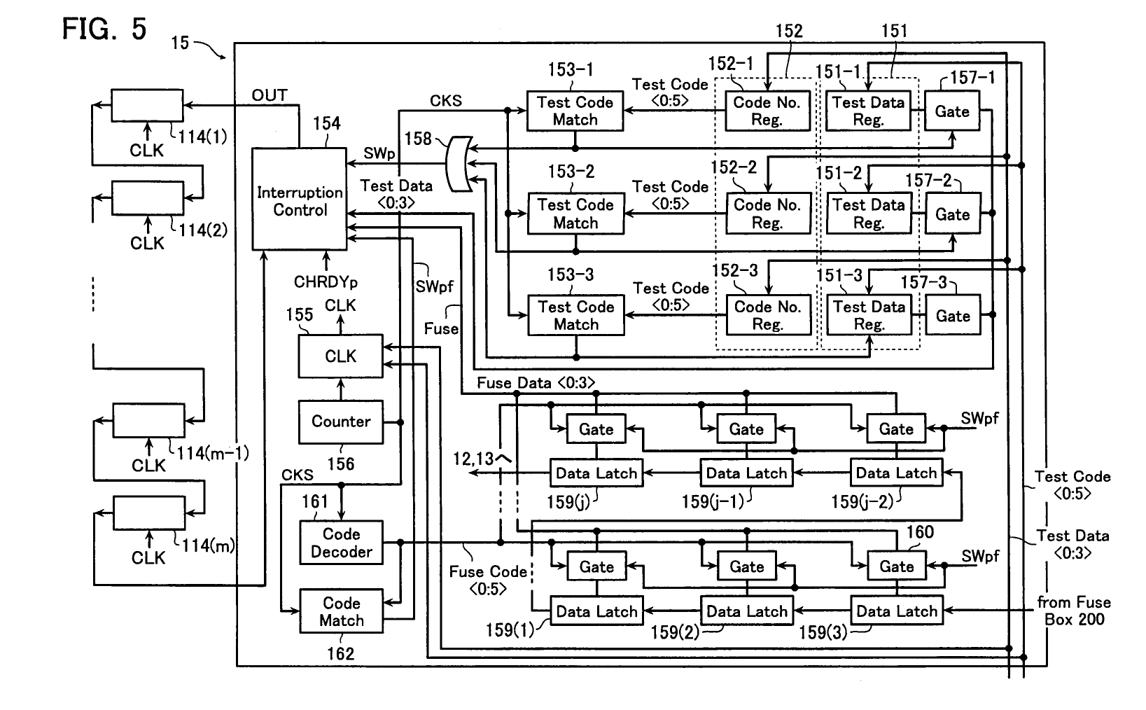

A third embodiment of the present invention will now be described below with reference to the accompanying drawings. The entire configuration of the semiconductor storage device is as illustrated in FIG. 1 and thus has the same configuration as the first embodiment. This embodiment, however, is different from the first embodiment in the configuration of the data transfer control circuit 15. FIG. 5 is a block diagram illustrating the configuration of the data transfer circuit 15 according to the third embodiment. The same reference numerals represent the same components as the second embodiment (FIG. 4) and detailed description thereof will be omitted.

This embodiment allows even fuse data stored in the fuse box 200 to be transferred to the memory macro 100 via the closed-loop path configured by the test data latch circuit 14 and the interruption control circuit 154. Therefore, as illustrated in FIG. 5, the data transfer control circuit 15 of this embodiment comprises, in addition to those in the second embodiment, a plurality of fuse data latch circuits 159 (1)-(j), gate circuits 160 provided corresponding to these fuse data latch circuits, a code decoder 161, and a code match detection circuit 162.

In addition, when a switch signal CHRDYp is in “L” state, the interruption control circuit 154 of this embodiment enables the input of fuse data FuseData<0:3> (selected state), while disabling the input of test data TestData<0:3> (non-selected state). Conversely, when a switch signal CHRRYp is in “H” state, it enables the input of test data TestData<0:3>, while disabling the input of fuse data FuseData<0:3>.

The fuse data latch circuits 159 (1)-(j) that are formed with a plurality of shift registers serially connected to each other serially transfer fuse data that is transferred from the fuse box 200. The fuse data latch circuits 159 (1)-(j) is also configured to allow data retained therein to be transferred to the row-fuse-data latch circuit 12 and the column fuse-data latch circuit 13 as usual.

However, when a switch signal CHRDYp is in “L” state, the interruption control circuit 154 allows only desired fuse data to be transferred through the above-mentioned closed-loop path. The necessary configuration for this involves the gate circuits 160, the code decoder 161, and the code match detection circuit 162.

The code decoder 161 generates a fuse code FuseCode<0:5> indicative of desired fuse data based on a code count signal CKS output from the clock counter. In addition, based on the code count signal CKS and the fuse code FuseCode<0:5>, the code match detection circuit 162 outputs a match signal SWpf to the interruption control circuit 154 and the gate circuits 160.

Upon receipt of the input match signal SWpf, the gate circuits 160 transfers the fuse data retained in the fuse data latch circuits 159 (1)-(j) to the interruption control circuit 154. Upon receipt of the match signal SWpf, the interruption control circuit 154 outputs the fuse data output from the gate circuits 160 to the test data latch circuit 14.

### Other Embodiments

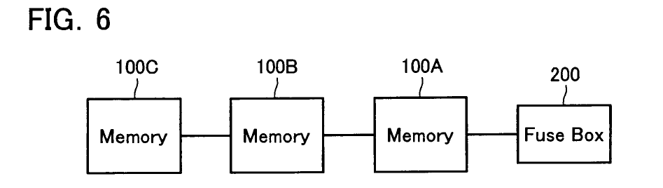

While embodiments of the present invention have been described, the present invention is not intended to be limited to the embodiments illustrated and described herein and various changes, additions or the like may be made thereto without departing from the spirit of the invention. For example, while the data transfer control circuit 15 has been described as constituting a part of the memory macro 100 in the above-mentioned embodiments, it may be configured as a chip independent of the memory macro. In addition, as illustrated in FIG. 6, the fuse box 200 may be shared between a plurality of memory macros 100A, 100B, 100C, . . . , and so on.

What is claimed is:

1. A semiconductor storage device with a test mode based on test data input from the outside, comprising:
a test data register temporarily retaining the test data;
a test code register temporarily retaining a test code corresponding to the test data;
a test-code-match detection circuit detecting a match between the test code retained in the test code register and a desired test code to output a match signal; and
a control circuit configured to, when the match signal is output, output the test data retained in the test data register to the first one of a plurality of shift registers in a test data latch circuit, the plurality of shift registers being serially connected to transfer the test data in a serial manner, and to start an operation of inputting the test data returned from the last one of the plurality of shift registers in the test data latch circuit.

2. The semiconductor storage device according to claim 1, further comprising: a clock signal generation circuit outputting a clock signal to prescribe operations of the control circuit and the test data latch circuit.

3. The semiconductor storage device according to claim 2, wherein the test-code-match detection circuit detects a match of the test code based on a code count signal as a frequency-demultiplied signal of the clock signal.

4. The semiconductor storage device according to claim 1, wherein
a plurality of the test data registers, the test code registers, and the test-code-match detection circuit are provided, and
the control circuit is configured to start the operation when any one of signals output from the plurality of the test-codes-match detection circuits is in a predetermined state.

5. The semiconductor storage device according to claim 1, wherein the control circuit is configured to be able to select a mode for transferring fuse data to the test data latch circuit.

6. The semiconductor storage device according to claim 2, further comprising a clock counter generating the code count signal.

7. The semiconductor storage device according to claim 1, further comprising:
a row-fuse-data latch circuit having shift registers serially connected to transfer row redundancy data in a serial manner, the row redundancy data being for replacement in the row direction for each unit in a memory cell array;
a column-fuse-data latch circuit having shift registers serially connected to transfer column redundancy data in a serial manner, the column redundancy data being for replacement in the column direction for each unit in a memory cell array; and
a fuse box retaining the row redundancy data and the column redundancy data.

8. The semiconductor storage device according to claim 1, wherein the control circuit is configured to be able to select a mode for transferring data retained by the fuse box to the test data latch circuit.

9. The semiconductor storage device according to claim 1, wherein the test data latch circuit in combination with the control circuit forms a closed-loop data transfer circuit.

10. A semiconductor storage device with a test mode based on test data input from the outside, comprising:
a test data register temporarily retaining the test data;
a test code register temporarily retaining a test code corresponding to the test data;
a test-code-match detection circuit detecting a match between the test code retained in the test code register and a desired test code to output a match signal;
a test data latch circuit having a plurality of shift registers serially connected to transfer the test data in a serial manner; and
a control circuit configured to, when the match signal is output, output the test data retained in the test data register to the first one of the plurality of shift registers in the test data latch circuit, and to start an operation of inputting the test data returned from the last one of the plurality of shift registers in the test data latch circuit.

11. The semiconductor storage device according to claim 10, further comprising a clock signal generation circuit outputting a clock signal to prescribe operations of the control circuit and the test data latch circuit.

12. The semiconductor storage device according to claim 11, wherein the test-code-match detection circuit detects a match of the test code based on a code count signal as a frequency-demultiplied signal of the clock signal.

13. The semiconductor storage device according to claim 10, wherein
a plurality of the test data registers, the test code registers, and the test-code-match detection circuit are provided, and
the control circuit is configured to start the operation when any one of signals output from the plurality of the test-codes-match detection circuits is in a predetermined state.

14. The semiconductor storage device according to claim 10, wherein the control circuit is configured to be able to select a mode for transferring fuse data to the test data latch circuit.

15. The semiconductor storage device according to claim 12, further comprising: a clock counter generating the code count signal.

16. The semiconductor storage device according to claim 10, further comprising:
a row-fuse-data latch circuit having shift registers serially connected to transfer row redundancy data in a serial manner, the row redundancy data being for replacement in the row direction for each unit in a memory cell array;
a column-fuse-data latch circuit having shift registers serially connected to transfer column redundancy data in a serial manner, the column redundancy data being for replacement in the column direction for each unit in a memory cell array; and
a fuse box retaining the row redundancy data and the column redundancy data.

17. The semiconductor storage device according to claim 10, wherein the control circuit is configured to be able to select a mode for transferring data retained by the fuse box to the test data latch circuit.

18. The semiconductor storage device according to claim 10, wherein the test data latch circuit in combination with the control circuit forms a closed-loop data transfer circuit.
